(19) United States
(12) Patent Application Publication
(10) Pub. No.: US 2005/0051859 A1
(43) Pub. Date: Mar. 10, 2005

(54) LOOK DOWN IMAGE SENSOR PACKAGE

(75) Inventor: Paul Robert Hoffman, Chandler, AZ (US)

Correspondence Address: Serge J. Hodgson;Gunnison, McKay & Hodgson, L.L.P., 1900 Garden Road, Suite 220, Monterey, CA, 93940, US

(73) Assignee: Amkor Technology, Inc.

(21) Appl. No.: 10/040,027

(22) Filed: Oct. 25, 2001

(51) Int. Cl. H01L 31/0203

(52) U.S. Cl. 257/434

(57) ABSTRACT

An image sensor package includes a transparent substrate having an image sensor pocket. An image sensor is flip chip mounted to the transparent substrate such that the image sensor is located within the image sensor pocket. Since the image sensor is located within the image sensor pocket, the image sensor package is approximately the same thickness as the transparent substrate.

### BACKGROUND OF THE INVENTION

1. Field of the Invention

The present invention relates generally to the packaging of electronic components. More particularly, the present invention relates to an image sensor package and method of fabricating the same.

2. Description of the Related Art

Image sensors and assemblies are well known to those of skill in the art. In one conventional image sensor assembly, an image sensor was mounted to a printed circuit mother board or other substrate. After the image sensor was mounted, a housing was mounted around the image sensor and to the printed circuit mother board or other substrate. This housing provided a protective barrier around the image sensor, while at the same time, supported a window above the image sensor. During use, electromagnetic radiation passed through the window and struck the image sensor, which responded to the electromagnetic radiation.

As the art moved to smaller and lighter weight electronic devices, it became increasingly important that the size of the image sensor assembly used within these electronic devices was small and thin. However, the conventional image sensor assembly described above required a housing to support the window and to protect the image sensor. Disadvantageously, this housing was relatively bulky and extended upwards from the printed circuit mother board or other substrate a significant distance resulting in a relatively thick image sensor assembly.

### SUMMARY OF THE INVENTION

In accordance with one embodiment of the present invention, an image sensor package includes a transparent substrate having a rear surface and an image sensor coupled to the transparent substrate. The image sensor has a first surface having an active area. An underfill fills a region between the first surface of the image sensor and a rear surface of the transparent substrate.

To the extent that the image sensor has a different thermal coefficient of expansion than the transparent substrate, the underfill insures that the image sensor does not become dismounted from the substrate.

Further, the underfill contacts and protects the first surface of the image sensor including the active area. Thus, the underfill protects the active area against external moisture, dust and contamination. During use, electromagnetic radiation passes through the transparent substrate, through the underfill, which is transparent, and strikes the active area.

In accordance with an alternative embodiment of the present invention, an image sensor assembly includes a system board having an image sensor aperture. The image sensor assembly further includes a transparent substrate coupled to the system board and an image sensor coupled to the transparent substrate and located within the image sensor aperture. The image sensor includes a first surface facing towards the transparent substrate, the first surface having an active area. By locating the image sensor within the image sensor aperture of the system board, the overall height of the image sensor assembly is minimized.

In accordance with yet another alternative embodiment of the present invention, an image sensor package includes a transparent substrate having a base surface and a pocket sidewall. A trace is coupled to the base surface. An image sensor includes a first surface having an active area and a bond pad. A bump couples the bond pad to the trace such that the image sensor is located within an image sensor pocket of the transparent substrate defined by the base surface and the pocket sidewall.

Advantageously, the image sensor is located within the image sensor pocket resulting in a minimal thickness for the image sensor package. More particularly, space above a rear surface of the transparent substrate is not allocated for the image sensor. Accordingly, the image sensor package is approximately the same thickness as the transparent substrate.

In accordance another alternative embodiment of the present invention, an image sensor package includes a transparent substrate having a rear surface and a front surface. A rear trace is coupled to the rear surface and a front trace is coupled to the front surface. A via extends from the rear surface to the front surface and electrically couples the rear trace to the front trace. An image sensor includes a first surface having an active area and a bond pad. A bump couples the bond pad to the rear trace. A bead forms a seal between a periphery of the image sensor and the rear surface. A package body encloses the bead and a side of the image sensor.

The package body maximizes the reliability of the image sensor package by minimizing the possibility of failure of the bump and the associated dismounting of the image sensor from the transparent substrate. Further, the package body maximizes the reliability of the image sensor package by forming a redundant seal between the image sensor and the transparent substrate. In particular, the bead forms a first seal and the package body forms a second seal, which collectively protect the active area of the image sensor.

Also in accordance with one embodiment of the present invention, a method includes coupling an image sensor to a transparent substrate such that a first surface of the image sensor is adjacent to a first surface of the substrate, the first surface of the image sensor having an active area. An underfill is formed between the first surface of the image sensor and the first surface of the transparent substrate.

In accordance with another embodiment of the present invention, a method includes coupling an image sensor to a transparent substrate such that a first surface of the image sensor is adjacent to a first surface of the substrate, the first surface of the image sensor having an active area. The transparent substrate is coupled to a system board having an image sensor aperture such that the image sensor is located within the image sensor aperture.

In accordance with another alternative embodiment of the present invention, a method includes forming an image sensor pocket in a transparent substrate. A trace is formed, the trace being coupled to the transparent substrate. A bond pad on a first surface of an image sensor is coupled to the trace, wherein the image sensor is located within the image sensor pocket.

In accordance with yet another alternative embodiment of the present invention, a method includes forming a rear trace on a rear surface of a transparent substrate. A front trace is formed on a front surface of the transparent substrate. A via is formed extending between the front surface and the rear surface and electrically coupling the rear trace to the front trace. A bond pad on a first surface of an image sensor is coupled to the rear trace. A bead is formed between a periphery of the image sensor and the rear surface. A package body is formed to enclose the bead and a side of the image sensor.

In accordance with another embodiment of the present invention, a method includes forming a rear trace on a rear surface of a transparent substrate. A front trace is formed on a front surface of the transparent substrate. A via is formed extending between the front surface and the rear surface and electrically coupling the rear trace to the front trace. A bond pad on a first surface of the image sensor is coupled to the rear trace. An underfill is formed between the first surface of the image sensor and the rear surface of the transparent substrate.

The present invention is best understood by reference to the following detailed description when read in conjunction with the accompanying drawings.

### BRIEF DESCRIPTION OF THE DRAWINGS

FIG. 1 is a cross-sectional view of an image sensor package in accordance with one embodiment of the present invention.

FIG. 2 is a cross-sectional view of an image sensor assembly formed with the image sensor package of FIG. 1 in accordance with one embodiment of the present invention.

FIG. 3 is a cross-sectional view of an image sensor package in accordance with an alternative embodiment of the present invention.

FIG. 4 is a block diagram illustrating operations in a process for manufacturing the image sensor assembly of FIG. 2 in accordance with one embodiment of the present invention.

FIG. 5 is a cross-sectional view of an image sensor package in accordance with yet another alternative embodiment of the present invention.

FIG. 6 is a cross-sectional view of an image sensor assembly formed with the image sensor package of FIG. 5 in accordance with one embodiment of the present invention.

FIG. 7 is a cross-sectional view of an image sensor package in accordance with an alternative embodiment of the present invention.

FIG. 8 is a block diagram illustrating operations in a process for manufacturing the image sensor assembly of FIG. 6 in accordance with one embodiment of the present invention.

FIG. 9 is a cross-sectional view of an image sensor package in accordance with yet another alternative embodiment of the present invention.

FIG. 10 is a cross-sectional view of an image sensor assembly formed with the image sensor package of FIG. 9 in accordance with another embodiment of the present invention.

FIG. 11 is a cross-sectional view of an image sensor package in accordance with an alternative embodiment of the present invention.

FIG. 12 is a block diagram illustrating operations in a process for manufacturing the image sensor assembly of FIG. 10 in accordance with one embodiment of the present invention.

Common reference numerals are used throughout the drawings and detailed description to indicate like elements.

### DETAILED DESCRIPTION

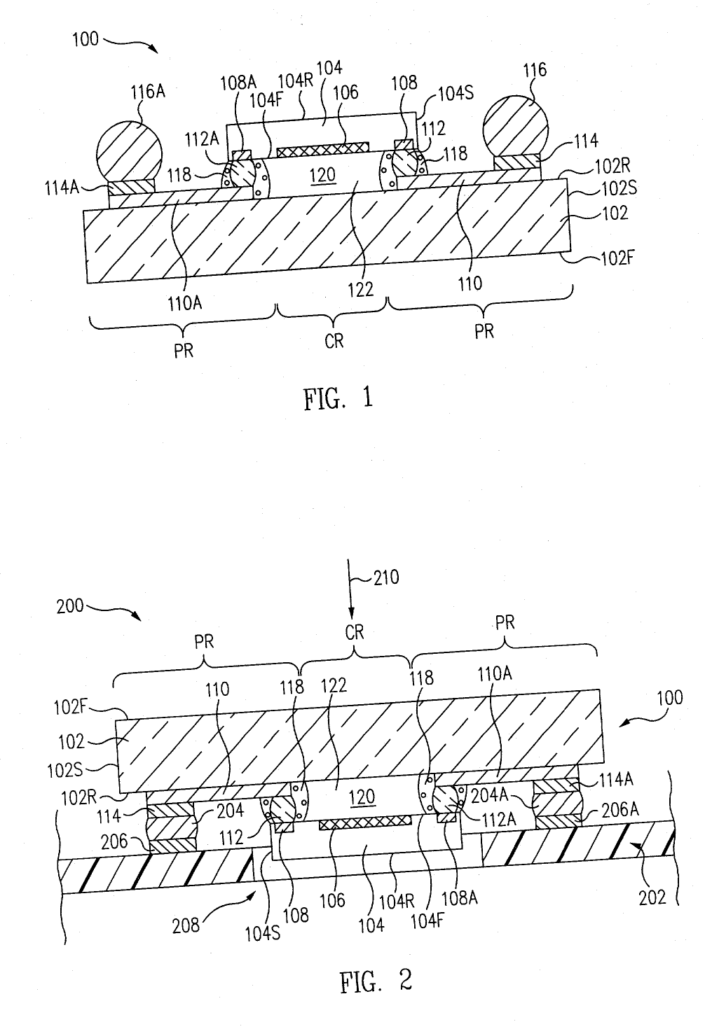

FIG. 1 is a cross-sectional view of an image sensor package 100 in accordance with one embodiment of the present invention. Image sensor package 100 includes a substrate 102 and an image sensor 104 mounted to substrate 102. Image sensor 104 includes an active area 106 on a front, e.g., first, surface 104F of image sensor 104, which faces towards substrate 102.

Generally, active area 106 is responsive to electromagnetic radiation, as is well known to those of skill in the art. For example, active area 106 is responsive to infrared radiation, ultraviolet light, and/or visible light. Illustratively, image sensor 104 is a CMOS image sensor device, a charge coupled device (CCD), or a pyroelectric device although other image sensors are used in other embodiments.

Generally, substrate 102 is transparent. In one embodiment, transparent means having a transparency sufficient for the proper operation of image sensor 104 to the electromagnetic radiation to which active area 106 of image sensor 104 is responsive, as those of skill in the art will understand in light of this disclosure.

In this embodiment, substrate 102 is integral, i.e., is a single piece and not a plurality of separate pieces connected together. Illustratively, substrate 102 is optical glass such as borosilicate glass although substrate 102 is formed of other transparent materials in other embodiments.

Image sensor 104 further includes a plurality of bond pads 108 on front surface 104F of image sensor 104. Bond pads 108 are connected to the internal circuitry of image sensor 104.

Substrate 102 includes a rear, e.g., first, surface 102R and a front, e.g., second, surface 102F opposite rear surface 102R. Formed on rear surface 102R of substrate 102 are electrically conductive rear traces 110, which include a first rear trace 110A. Substrate 102 is an electrical insulator or includes an electrically insulating layer on rear surface 102R.

Bond pads 108 are electrically and physically connected to corresponding rear traces 110 by electrically conductive bumps 112. Illustratively, bumps 112 are: (1) stud bumps, i.e., gold balls; (2) electrically conductive adhesive, e.g., epoxy, paste; (3) electrically conductive adhesive, e.g., epoxy, film; (4) solder; or (5) another electrically conductive and bondable material.

To illustrate, a first bond pad 108A of the plurality of bond pads 108 is electrically and physically connected to rear trace 110A by a first bump 112A of the plurality of bumps 112.

Formed on rear traces 110 are electrically conductive pads 114, which include a first pad 114A. Formed on pads 114 are electrically conductive interconnection balls 116, e.g., solder. To illustrate, pad 114A is formed on rear trace 110A. A first interconnection ball 116A of the plurality of interconnection balls 116 is formed on pad 114A. In one embodiment, rear traces 110 are covered with a dielectric protective layer such as a solder mask.

As set forth above, an electrically conductive pathway between bond pad 108A and interconnection ball 116A is formed by bump 112A, rear trace 110A and pad 114A. The other bond pads 108, bumps 112, rear traces 110, pads 114 and interconnection balls 116 are electrically connected to one another in a similar fashion and so are not discussed further to avoid detracting from the principals of the invention.

Although a particular electrically conductive pathway between bond pad 108A and interconnection ball 116A is described above, in light of this disclosure, it is understood that other electrically conductive pathways can be formed. For example, contact metallizations can be formed between the various electrical conductors, e.g., between bond pads 108 and bumps 112, between bumps 112 and rear traces 110, between rear traces 110 and pads 114, and/or between pads 114 and interconnection balls 116. Alternatively, pads 114 are not formed and interconnection balls 116 are formed directly on rear traces 110.

As yet another alternative, interconnection balls 116 are distributed in an array format to form a ball grid array (BGA) type package. Alternatively, interconnection balls 116 (or pads 114 and interconnection balls 116) are not formed, e.g., to form a metal land grid array (LGA) type package. Other electrically conductive pathway modifications will be obvious to those of skill in the art.

A bead 118 contacts the periphery of image sensor 104 and secures the periphery of image sensor 104 to substrate 102. Typically, bead 118 is an electrical insulator. In one embodiment, bead 118 extends slightly under image sensor 104 and contacts the periphery of front surface 104F adjacent a side 104S of image sensor 104. In another embodiment, bead 118 further contacts side 104S of image sensor 104. In yet another embodiment, bead 118 extends over image sensor 104 and contacts the periphery of a rear, e.g., second, surface 104R opposite front surface 104F of image sensor 104 or, alternatively, entirely contacts and encloses rear surface 104R.

In this embodiment, bead 118 encloses bumps 112. To the extent that image sensor 104 has a different thermal coefficient of expansion than substrate 102, bead 118 insures that image sensor 104 does not become dismounted from substrate 102, i.e., prevents failure of bumps 112.

Further, bead 118 forms a seal between the periphery of image sensor 104 and substrate 102. Thus, image sensor 104, bead 118, and substrate 102 define a cavity 120, which is sealed. In particular, active area 106 is located within cavity 120, which is sealed to protect active area 106 against external moisture, dust and contamination. Generally, cavity 120 contains a medium 122, which is transparent. In one embodiment, medium 122 is air.

FIG. 2 is a cross-sectional view of an image sensor assembly 200 formed with image sensor package 100 of FIG. 1 in accordance with one embodiment of the present invention. Referring now to FIG. 2, image sensor assembly 200 includes image sensor package 100 and a system board 202 such as a printed circuit mother board, sometimes called a system PCB or a larger substrate.

More particularly, image sensor package 100 is mounted to system board 202. Image sensor package 100 is mounted to system board 202 by electrically conductive system board interconnects 204, e.g., solder, sometimes called solder interconnects. Illustratively, system board interconnects 204 are formed by re-flowing interconnection balls 116 (FIG. 1).

More particularly, pads 114 of image sensor package 100 are physically and electrically connected to electrically conductive terminals 206 of system board 202 by system board interconnects 204. To illustrate, pad 114A is physically and electrically connected to a first terminal 206A of the plurality of terminals 206 by a first system board interconnect 204A of the plurality of system board interconnects 204. The other pads 114 are physically and electrically connected to the other terminals 206 by the other system board interconnects 204 in a similar manner and so are not discussed further to avoid detracting from the principles of the invention.

Advantageously, by mounting image sensor 104 to substrate 102 as a flip chip, image sensor 104 is positionally aligned to within tight tolerances. More particularly, since bond pads 108 of image sensor 104 are connected to rear traces 110, image sensor 104 is inherently aligned to rear traces 110. Further, since rear traces 110 are connected to terminals 206, rear traces 110 are inherently aligned to terminals 206 and thus system board 202. Overall, image sensor 104 is inherently aligned to system board 202. By precisely aligning image sensor 104, the performance of image sensor package 100 is improved compared to a conventional image sensor assembly in which bond pads were wirebonded to traces.

Generally, substrate 102 of image sensor package 100 is mounted to system board 202. In the embodiment illustrated in FIG. 2, substrate 102 is mounted to system board 202 by terminals 206, system board interconnects 204, and pads 114. However, in an alternative embodiment, pads 114 are not formed such that rear traces 110 are directly mounted to terminals 206 by system board interconnects 204.

System board 202 is formed with an image sensor aperture 208. As shown in FIG. 2, image sensor 104 of image sensor package 100 is located within image sensor aperture 208 of system board 202. In this manner, the overall height of image sensor assembly 200 is minimized.

Once mounted, front surface 102F of substrate 102 faces away from system board 202 and is exposed. Electromagnetic radiation 210, e.g., an image or data, is directed at and strikes front surface 102F of substrate 102. Electromagnetic radiation 210 passes through substrate 102, through medium 122 and strikes active area 106. Image sensor 104 responds to electromagnetic radiation 210 as is well known to those of skill in the art.

However, in an alternative embodiment, active area 106 of image sensor 104 transmits electromagnetic radiation. For example, image sensor 104 is a light emitting diode (LED) micro-display. In accordance with this embodiment, electromagnetic radiation transmitted by active area 106 passes through medium 122, through substrate 102, and emanates from image sensor package 100. For simplicity, in the above and following discussions, active area 106 as a receiver of electromagnetic radiation is set forth. However, in light of this disclosure, those of skill in the art will recognize that generally active area 106 can be a receiver of electromagnetic radiation, a transmitter of electromagnetic radiation, or a transceiver, i.e., a transmitter and a receiver, of electromagnetic radiation.

Substrate 102 includes a central region CR and a peripheral PR. Central region CR is aligned with and is above active area 106. During use, electromagnetic radiation 210 unobstructedly passes through central region CR of substrate 102 and cavity 120.

Peripheral region PR surrounds central region CR and is around a periphery of substrate 102 adjacent a side 102S of substrate 102. Rear traces 110 are formed on peripheral region PR of substrate 102. Accordingly, bumps 112, rear traces 110, pads 114, and system board interconnects 204 do not obstruct or distort electromagnetic radiation 210 striking active area 106.

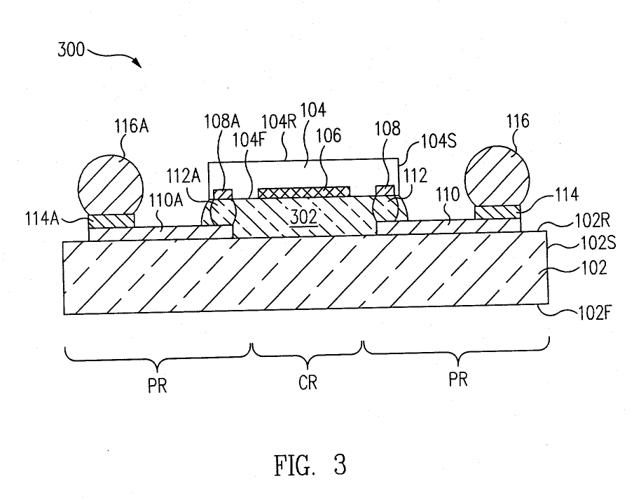

FIG. 3 is a cross-sectional view of an image sensor package 300 in accordance with an alternative embodiment of the present invention. Image sensor package 300 of FIG. 3 is similar to image sensor package 100 of FIG. 1 and only the significant differences are discussed below.

Referring now to FIG. 3, image sensor package 300 includes a transparent underfill 302, sometimes called an underfill material, which completely underfills image sensor 104. More particularly, transparent underfill 302 entirely fills the region between front surface 104F of image sensor 104 and rear surface 102R of substrate 102. Transparent underfill 302 is transparent.

In one embodiment, transparent underfill 302 further contacts side 104S of image sensor 104. In yet another embodiment, transparent underfill 302 extends over image sensor 104 and contacts the periphery of rear surface 104R or, alternatively, entirely contacts and encloses rear surface 104R.

In this embodiment, transparent underfill 302 encloses bumps 112. To the extent that image sensor 104 has a different thermal coefficient of expansion than substrate 102, transparent underfill 302 insures that image sensor 104 does not become dismounted from substrate 102, i.e., prevents failure of bumps 112.

Further, transparent underfill 302 contacts and protects front surface 104F of image sensor 104 including active area 106. Thus, transparent underfill 302 protects active area 106 against external moisture, dust and contamination.

Referring now to FIGS. 2 and 3 together, in one embodiment, image sensor package 300 of FIG. 3 is mounted to system board 202 in a manner similar to that described above with regards to image sensor package 100. During use, electromagnetic radiation 210 passes through substrate 102, through transparent underfill 302, and strikes active area 106.

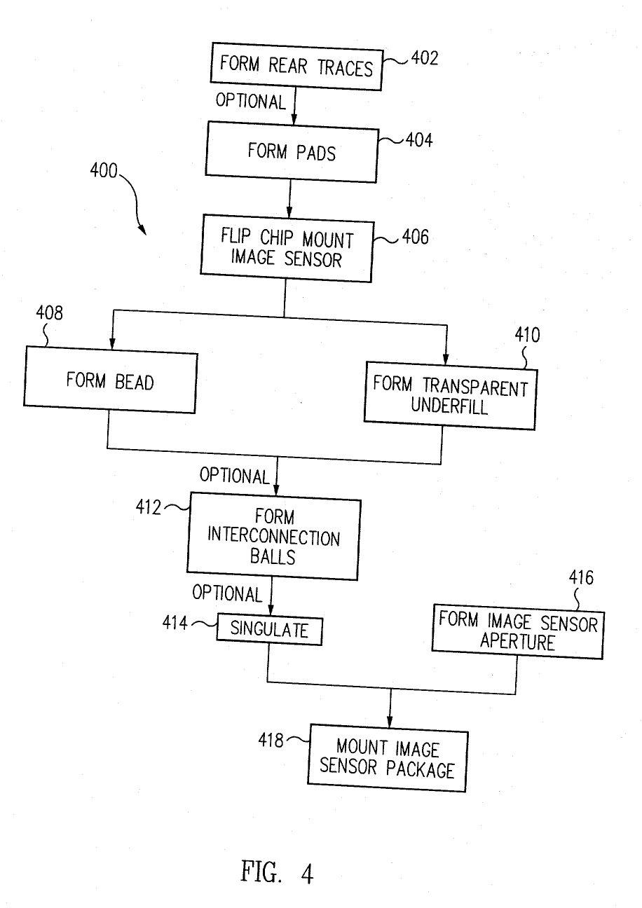

FIG. 4 is a block diagram 400 illustrating operations in a process for manufacturing image sensor assembly 200 of FIG. 2 in accordance with one embodiment of the present invention.

Referring now to FIGS. 2 and 4 together, in a Form Rear Traces Operation 402, rear traces 110 are formed on rear surface 102R of substrate 102. Illustratively, an electrically conductive layer, e.g., a copper or copper containing layer, is formed on rear surface 102R of substrate 102. The electrically conductive layer is formed using any one of a number of techniques, e.g., by plating or vapor deposition such as sputtering, physical vapor deposition (PVD), and/or plasma enhanced chemical vapor deposition (PECVD) processing. The electrically conductive layer is patterned, e.g., by photo imaging, to form rear traces 110. Alternatively, the electrically conductive layer is selectively formed to form rear traces 110.

Alternatively, rear traces 110 are formed separate from substrate 102 and then mounted, e.g., with adhesive, to rear surface 102R of substrate 102.

Optionally, in a Form Pads Operation 404, pads 114 are formed on rear traces 110. Illustratively, a mask, e.g., photoresist, is formed on substrate 102 to expose portions of rear traces 110. Pads 114 are formed, e.g., by plating, on the exposed portions of rear traces 110. The mask is then removed.

In a Flip Chip Mount Image Sensor Operation 406, image sensor 104 is flip chip mounted to substrate 102 by bumps 112 such that front surface 104F of image sensor 104 is adjacent to rear surface 102R of substrate 102. Illustratively, image sensor 104 is aligned with substrate 102 using any one of a number of alignment techniques, e.g., image sensor 104 is optically or mechanically aligned, and attached to substrate 102.

Image sensor 104 is attached to substrate 102 using any one of a number of techniques. For example, solder bumps 112 are formed on bond pads 108 of image sensor 104 or, alternatively, on rear traces 110, and solder bumps 112 are reflowed to attach bond pads 108 to rear traces 110.

Alternatively, bond pads 108 of image sensor 104 are attached to rear traces 110 by bumps 112 formed of electrically conductive adhesive, e.g., epoxy, paste or film, which is thermally or optically cured.

As a further alternative, bond pads 108 of image sensor 104 are attached to rear traces 110 by thermal or thermosonic bonding of gold bumps 112 formed on bond pads 108, or, alternatively, on rear traces 110.

In light of this disclosure, those of skill in the art will understand that bumps 112 are interconnects that attach image sensor 104 to substrate 102 and that a variety of bumps 112, i.e., interconnects, can be used other than those set forth above.

In a Form Bead Operation 408, bead 118 is formed around the periphery of image sensor 104. Bead 118 is formed in a manner that prevents bead 118 from completely filling the space between image sensor 104 and substrate 102. More particularly, bead 118 does not contact active area 106 of image sensor 104. In one embodiment, bead 118 is formed from a limited flow material. For example, an epoxy dispense material is applied using a needle dispenser and then cured to form bead 118.

Optionally, referring now to FIGS. 1, 2 and 4 together, in a Form Interconnection Balls Operation 412, substrate 102 is populated with interconnection balls 116 (FIG. 1). More particularly, interconnection balls 116 are formed on pads 114.

Optionally, in a Singulate Operation 414, substrate 102 is singulated from an array substrate, e.g., a sheet of optical glass having a plurality of substrates 102 integrally connected together. More particularly, a plurality of image sensor packages 100 are formed simultaneously on an array substrate during Operations 402, 404, 406, 408, and 412. During Singulate Operation 414, the array substrate is singulated to form a plurality of individual image sensor packages 100.

In a Form Image Sensor Aperture Operation 416, image sensor aperture 208 is formed in system board 202. In a Mount Image Sensor Package Operation 418, image sensor package 100 is mounted to system board 202 such that image sensor 104 is placed within image sensor aperture 208 to complete fabrication of image sensor assembly 200. More particularly, substrate 102 is mounted to system board 202 by forming system board interconnects 204 between pads 114 and terminals 206. In one embodiment, system board interconnects 204 are formed by reflowing interconnection balls 116 (FIG. 1).

Referring now to FIGS. 2, 3 and 4 together, in another alternative embodiment, image sensor package 300 of FIG. 3 is mounted to system board 202 of FIG. 2 instead of image sensor package 100. In accordance with this embodiment, instead of Form Bead Operation 408, a Form Transparent Underfill Operation 410 is performed to form transparent underfill 302.

Illustratively, a liquid encapsulant such as a liquid epoxy or other optically clear sealant material is applied and drawn between image sensor 104 and substrate 102 by capillary force. The liquid encapsulant is then cured thermally or optically to form transparent underfill 302. The other operations of block diagram 400 in accordance with this embodiment are as described above and so are not discussed further to avoid detracting from the principals of the invention.

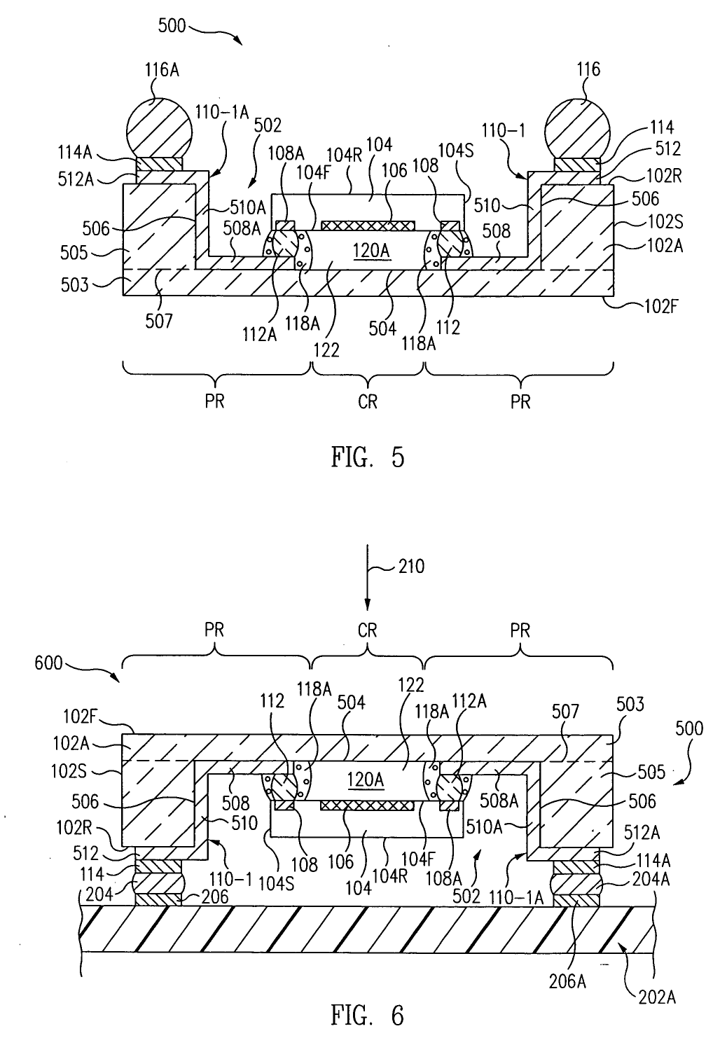

FIG. 5 is a cross-sectional view of an image sensor package 500 in accordance with yet another alternative embodiment of the present invention. Image sensor package 500 of FIG. 5 is similar to image sensor package 100 of FIG. 1 and only the significant differences are discussed below.

Referring now to FIG. 5, substrate 102A includes an image sensor pocket 502, sometimes called a recess, compartment, or cavity. More particularly, image sensor pocket 502 is defined by a base surface 504, e.g., a third surface, and a pocket sidewall 506, e.g., a fourth surface, of substrate 102A.

In this embodiment, front surface 102F and rear surface 102R of substrate 102A are parallel to base surface 504. Further, pocket sidewall 506 is perpendicular to and extends between base surface 504 and rear surface 102R. Rear surface 102R extends around the entire periphery of image sensor pocket 502. Although base surface 504 and pocket sidewall 506 are illustrated as distinct planar surfaces, generally, only the portion of base surface 504 to which image sensor 104 is mounted should be planar. In alternative embodiments, base surface 504 and pocket sidewall 506 are curved surfaces, e.g., concave surfaces, and can be distinct surfaces or parts of a single continuous surface.

In one embodiment, substrate 102A includes a base 503 and a pocket ring 505 connected together at the dashed line 507. Illustratively, base 503 and pocket ring 505 are laminated together, glued together, or otherwise put together. In one embodiment, base 503 is a rectangular piece and pocket ring 505 is a rectangular annulus. Alternatively, substrate 102A is integral, i.e., base 503 and pocket ring 505 are parts of a single piece and are not separate pieces connected together.

Bond pads 108 of image sensor 104 are electrically and physically connected to rear traces 110-1 by bumps 112 in a manner similar to that described above with regards to bond pads 108, bumps 112 and rear traces 110 of image sensor package 100 of FIG. 1.

A bead 118A contacts the periphery of image sensor 104 and secures the periphery of image sensor 104 to base surface 504 of substrate 102A. Typically, bead 118A is an electrical insulator. In one embodiment, bead 118A extends slightly under image sensor 104 and contacts the periphery of front surface 104F adjacent side 104S of image sensor 104. In another embodiment, bead 118A further contacts side 104S of image sensor 104. In yet another embodiment, bead 118A extends over image sensor 104 and contacts the periphery of rear surface 104R or, alternatively, entirely contacts and encloses rear surface 104R.

In this embodiment, bead 118A encloses bumps 112. To the extent that image sensor 104 has a different thermal coefficient of expansion than substrate 102A, bead 118A insures that image sensor 104 does not become dismounted from substrate 102A, i.e., prevents failure of bumps 112.

Further, bead 118A forms a seal between the periphery of image sensor 104 and base surface 504 of substrate 102A. Thus, image sensor 104, bead 118A, and base surface 504 of substrate 102A define a cavity 120A, which is sealed. In particular, active area 106 is located within cavity 120A, which is sealed to protect active area 106 against external moisture, dust and contamination. Generally, cavity 120A contains a medium 122, which is transparent.

Rear traces 110-1 have lower, e.g., first, portions 508 extending along base surface 504 to pocket sidewall 506. Rear traces 110-1 further have vertical, e.g., second, portions 510 extending up pocket sidewall 506 from base surface 504 to rear surface 102R. Rear traces 110-1 further have upper, e.g., third, portions 512 extending along rear surface 102R. In this embodiment, rear traces 110-1 are integral, i.e., lower portions 508, vertical portions 510 and upper portions 512 are integral. Generally, rear traces 110-1 extend from base surface 504 along pocket sidewall 506 to rear surface 102R.

To illustrate, a first rear trace 110-1A of the plurality of rear traces 110-1 includes a first lower portion 508A, a first vertical portion 510A, and a first upper portion 512A of the plurality of lower portions 508, vertical portions 510, and upper portions 512, respectively. Lower portion 508A, vertical portion 510A, and upper portion 512A are integral. The other rear traces 110-1 include lower portions 508, vertical portions 510, and upper portions 512 in a similar manner and so are not discussed further to avoid detracting from the principles of the invention.

Advantageously, image sensor 104 is located within image sensor pocket 502 resulting in a minimal thickness for image sensor package 500. More particularly, space above rear surface 102R of substrate 102A is not allocated for image sensor 104. Accordingly, image sensor package 500 is approximately the same thickness as substrate 102A.

In this embodiment, rear surface 104R of image sensor 104 is below rear surface 102R of substrate 102A, i.e., image sensor 104 is entirely within image sensor pocket 502. Stated another way, rear surface 104R is closer to base surface 504 than rear surface 102R. However, in alternative embodiments, rear surface 104R of image sensor 104 is coplanar with or above rear surface 102R of substrate 102A, i.e., rear surface 104R is the same distance as or further from base surface 504 than rear surface 102R.

Pads 114 and interconnection balls 116 are formed, if at all, on upper portions 512 of rear traces 110-1 in a manner similar to that described above with regards to pads 114, interconnection balls 116 and rear traces 110 of image sensor package 100 of FIG. 1.

FIG. 6 is a cross-sectional view of an image sensor assembly 600 formed with image sensor package 500 of FIG. 5 in accordance with one embodiment of the present invention. Referring now to FIG. 6, image sensor assembly 600 includes image sensor package 500 and a system board 202A.

More particularly, image sensor package 500 is mounted to system board 202A. Image sensor package 500 is mounted to system board 202A by electrically conductive system board interconnects 204. Illustratively, system board interconnects 204 are formed by re-flowing interconnection balls 116 (FIG. 5).

In accordance with this embodiment, system board 202A is formed without an image sensor aperture. As shown in FIG. 6, since image sensor 104 of image sensor package 500 fits within image sensor pocket 502 of substrate 102A, an aperture to accommodate image sensor 104 within system board 202A is unnecessary.

Once mounted, front surface 102F of substrate 102A faces away from system board 202A and is exposed. Electromagnetic radiation 210 is directed at and strikes front surface 102F of substrate 102A. Electromagnetic radiation 210 passes through substrate 102A, through medium 122 and strikes active area 106. Image sensor 104 responds to electromagnetic radiation 210 as is well known to those of skill in the art.

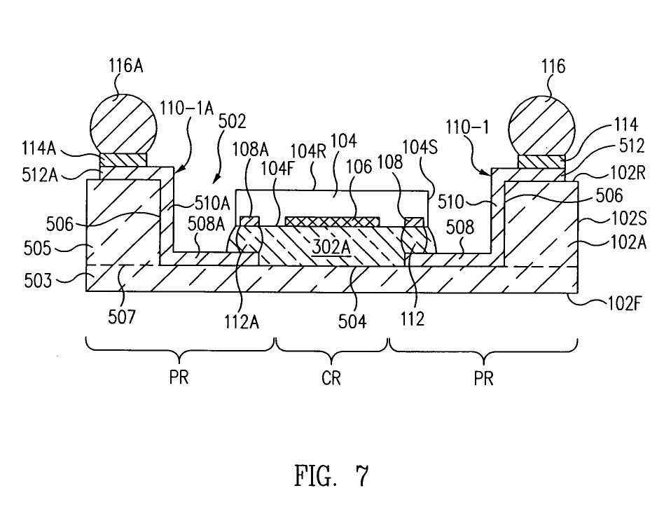

FIG. 7 is a cross-sectional view of an image sensor package 700 in accordance with an alternative embodiment of the present invention. Image sensor package 700 of FIG. 7 is similar to image sensor package 500 of FIG. 5 and only the significant differences in discussed below.

Referring now to FIG. 7, image sensor package 700 includes a transparent underfill 302A, sometimes called an underfill material, which completely underfills image sensor 104. More particularly, transparent underfill 302A entirely fills the region between front surface 104F of image sensor 104 and base surface 504 of substrate 102A. Transparent underfill 302A is transparent.

In one embodiment, transparent underfill 302A further contacts side 104S of image sensor 104. In yet another embodiment, transparent underfill 302A extends over image sensor 104 and contacts the periphery of rear surface 104R or, alternatively, entirely contacts and encloses rear surface 104R.

In this embodiment, transparent underfill 302A encloses bumps 112. To the extent that image sensor 104 has a different thermal coefficient of expansion than substrate 102A, transparent underfill 302A insures that image sensor 104 does not become dismounted from substrate 102A, i.e., prevents failure of bumps 112.

Further, transparent underfill 302A contacts and protects front surface 104F of image sensor 104 including active area 106. Thus, transparent underfill 302A protects active area 106 against external moisture, dust and contamination.

Referring now to FIGS. 6 and 7 together, in one embodiment, image sensor package 700 of FIG. 7 is mounted to system board 202A in a manner similar to that described above with regards to image sensor package 500. During use, electromagnetic radiation 210 passes through substrate 102A, through transparent underfill 302A, and strikes active area 106.

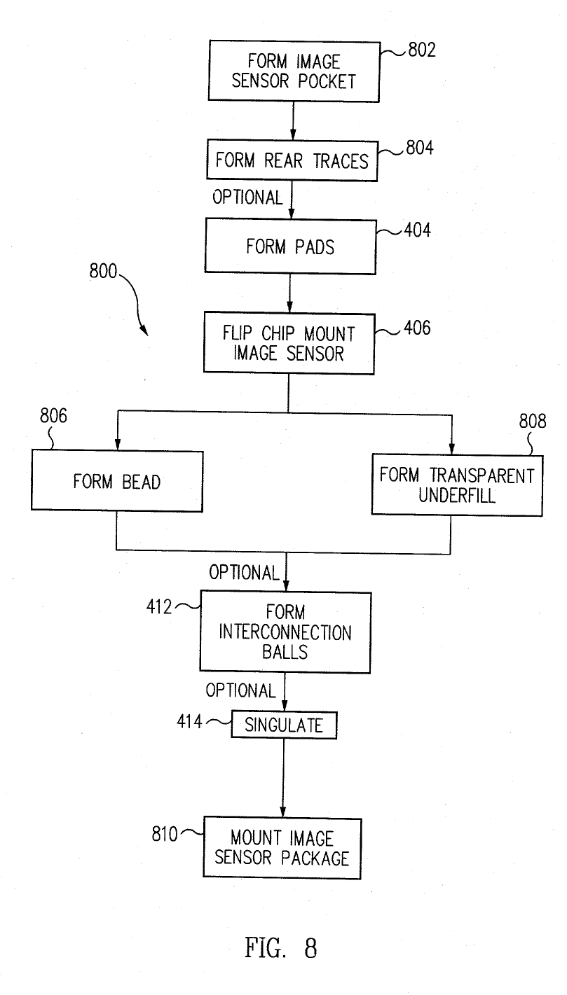

FIG. 8 is a block diagram 800 illustrating operations in a process for manufacturing image sensor assembly 600 of FIG. 6 in accordance with one embodiment of the present invention.

Referring now to FIGS. 6 and 8 together, in a Form Image Sensor Pocket Operation 802, image sensor pocket 502 is formed in substrate 102A. Illustratively, image sensor pocket 502 is formed by etching. For example, a mask, e.g., photoresist, is applied to substrate 102A and patterned to expose a portion of rear surface 102R of substrate 102A. This expose portion is then removed with an etchant. The mask is then removed.

Alternatively, substrate 102A and image sensor pocket 502 are formed by connecting together base 503 and pocket ring 505. For example, pocket ring 505 is laminated, glued, or otherwise put together with base 503 to form substrate 102A and image sensor pocket 502.

In a Form Rear Traces Operation 804, rear traces 110-1 are formed on substrate 102A. Illustratively, an electrically conductive layer, e.g., a copper or copper containing layer, is formed on base surface 504, pocket sidewall 506 and rear surface 102R of substrate 102A. The electrically conductive layer is formed using any one of a number of techniques, e.g., by plating or vapor deposition such as sputtering, physical vapor deposition (PVD), and/or plasma enhanced chemical vapor deposition (PECVD) processing. The electrically conductive layer is patterned, e.g., by photo imaging, to form rear traces 110-1. Alternatively, the electrically conductive layer is selectively formed to form rear traces 110-1.

Alternatively, rear traces 110-1 are formed separate from substrate 102A and then mounted, e.g., with adhesive, to base surface 504, pocket sidewall 506 and rear surface 102R of substrate 102A.

Form Pads Operation 404 is performed, if at all, as discussed above in reference to FIG. 4. Flip Chip Mount Image Sensor Operation 406 is also performed as discussed above in reference to FIG. 4 resulting in the formation of bumps 112 between first portions 508 of rear traces 110-1 and bond pads 108.

In a Form Bead Operation 806, bead 118A is formed around the periphery of image sensor 104. Bead 118A is formed in a manner that prevents bead 118A from completely filling the space between image sensor 104 and base surface 504 of substrate 102A. More particularly, bead 118A does not contact active area 106 of image sensor 104. In one embodiment, bead 118A is formed from a limited flow material. For example, an epoxy dispense material is applied using a needle dispenser and then cured to form bead 118A.

Form Interconnection Balls Operation 412 and Singulate Operation 414 are performed, if at all, as discussed above in reference to FIG. 4. In a Mount Image Sensor Package Operation 810, image sensor package 500 is mounted to system board 202A. More particularly, image sensor package 500 is mounted to system board 202A by forming system board interconnects 204 between pads 114 and terminals 206. In one embodiment, system board interconnects 204 are formed by reflowing interconnection balls 116 (FIG. 5).

Referring now to FIGS. 6, 7 and 8 together, in another alternative embodiment, image sensor package 700 of FIG. 7 is mounted to system board 202A of FIG. 6 instead of image sensor package 500. In accordance with this embodiment, instead of Form Bead Operation 806, a Form Transparent Underfill Operation 808 is performed to form transparent underfill 302A.

Illustratively, a liquid encapsulant is applied and drawn between image sensor 104 and base surface 504 of substrate 102A by capillary force. The liquid encapsulant is then cured thermally or optically to form transparent underfill 302A. The other operations of block diagram 800 in accordance with this embodiment are as described above and so are not discussed further to avoid detracting from the principals of the invention.

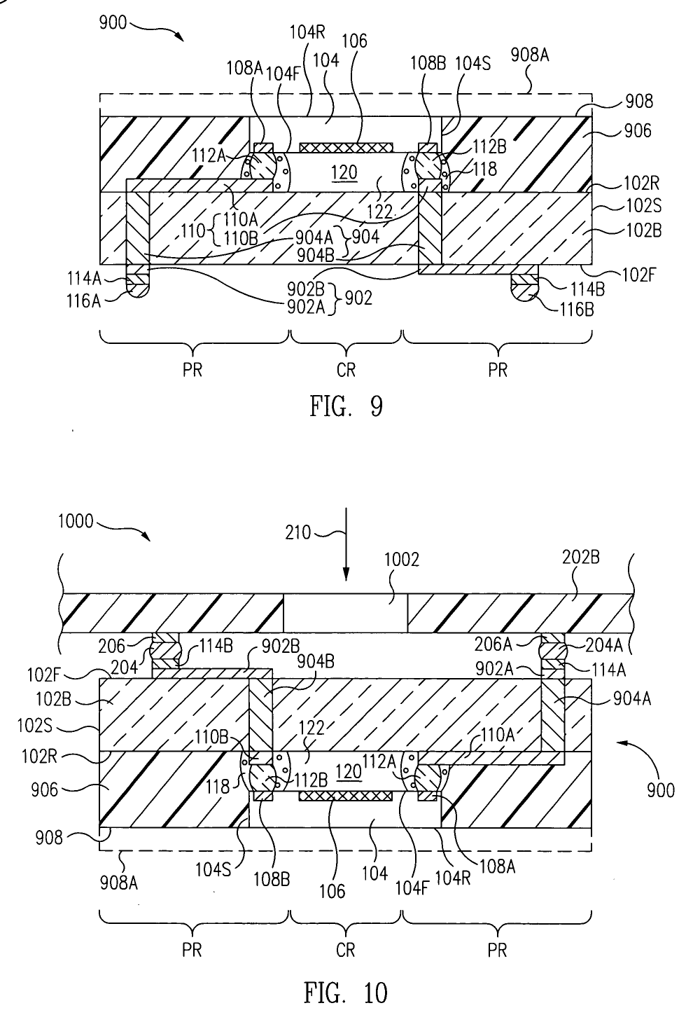

FIG. 9 is a cross-sectional view of an image sensor package 900 in accordance with yet another alternative embodiment of the present invention. Image sensor package 900 of FIG. 9 is similar to image sensor package 100 of FIG. 1 and only the significant differences are discussed below.

Referring now to FIG. 9, formed on front surface 102F of substrate 102B are a plurality of electrically conductive front traces 902, which include a first front trace 902A. Rear traces 110 on rear surface 102R of substrate 102B are electrically connected to front traces 902 by electrically conductive vias 904, which include a first via 904A. Vias 904 extend through substrate 102B from rear surface 102R to front surface 102F.

Formed on front traces 902 are electrically conductive pads 114. Formed on pads 114 are electrically conductive interconnection balls 116.

To illustrate, bond pad 108A of image sensor 104 is electrically and physically connected to rear trace 110A by bump 112A. Rear trace 110A is electrically connected to front trace 902A by via 904A. Formed on front trace 902A is pad 114A. Formed on pad 114A is interconnection ball 116A.

As set forth, an electrically conductive pathway between bond pad 108A and interconnection ball 116A is formed by bump 112A, rear trace 110A, via 904A, front trace 902A, and pad 114A. The other bond pads 108, bumps 112, rear traces 110, vias 904, front traces 902, pads 114, and interconnection balls 116 are electrically connected to one another in a similar fashion and so are not discussed further to avoid detracting from the principals of the invention.

Although a particular electrically conductive pathway between bond pad 108A and interconnection ball 116A is described above, in light of this disclosure, it is understood that other electrically conductive pathways can be formed. For example, contact metallizations can be formed between the various electrical conductors, e.g., between bond pads 108 and bumps 112, between bumps 112 and rear traces 110, between front traces 902 and pads 114, and/or between pads 114 and interconnection balls 116. Alternatively, pads 114 are not formed and interconnection balls 116 are formed directly on front traces 902.

In one embodiment, rear traces 110 are lands aligned horizontally in the view of FIG. 9 with vias 904, bumps 112 and bond pads 108. To illustrate, a second rear trace 110B of the plurality of rear traces 110 is a land. Rear trace 110B is aligned with a second via 904B of the plurality of vias 904, with a second bump 112B of the plurality of bumps 112 and with a second bond pad 108B of the plurality of bond pads 108.

Alternatively, rear traces 110 are metallizations, which extend along rear surface 102R of substrate 102B such that vias 904 are not aligned with bumps 112 and bond pads 108. To illustrate, rear trace 110A extends horizontally in the view of FIG. 9 from bump 112A (and bond pad 108A) to via 904A. Stated another way, via 904A is offset from bump 112A, and rear trace 110A extends along rear surface 102R to electrically connect via 904A to bump 112A.

Similarly, front traces 902 are lands aligned horizontally in the view of FIG. 9 with vias 904, pads 114 and interconnection balls 116. To illustrate, front trace 902A is a land. Front trace 902A is aligned with via 904A, with pad 114A and with interconnection ball 116A.

Alternatively, front traces 902 are metallizations, which extend along front surface 102F of substrate 102B such that vias 904 are not aligned with pads 114 and interconnection balls 116. To illustrate, a second front trace 902B of the plurality of front traces 902 extends horizontally in the view of FIG. 9 from second via 904B to a second pad 114B of the plurality of pads 114. Stated another way, via 904B is offset from pad 114B, and front trace 902B extends along front surface 102F to electrically connect via 904B to pad 114B. A second interconnection ball 116B of the plurality of interconnection balls 116 is formed on pad 114B.

As yet another alternative, interconnection balls 116 are distributed in an array format to form a ball grid array (BGA) type package. Alternatively, interconnection balls 116 (or pads 114 and interconnection balls 116) are not formed, e.g., to form a metal land grid array (LGA) type package. Other electrically conductive pathway modifications will be obvious to those of skill in the art.

Image sensor package 900 further includes a package body 906, e.g., a molded encapsulant or electronic mold compound, sometimes called a mold material. Package body 906 encloses bead 118, any exposed portions of rear traces 110 and rear surface 102R of substrate 102B, and side 104S of image sensor 104.

Package body 906 maximizes the reliability of image sensor package 900 by minimizing the possibility of failure of bumps 112 and the associated dismounting of image sensor 104 from substrate 102B. Further, package body 906 maximizes the reliability of image sensor package 900 by forming a redundant seal between image sensor 104 and substrate 102B. In particular, bead 118 forms a first seal around cavity 120 and package body 906 forms a second seal around bead 118 and cavity 120. Since active area 106 is located within cavity 120, which is sealed by both bead 118 and package body 906, active area 106 is extremely well protected against external moisture, dust and contamination thus maximizing the reliability of image sensor package 900.

As shown in FIG. 9, package body 906 includes an exposed upper, e.g., first, surface 908. Exposed upper surface 908 of package body 906 is coplanar with rear surface 104R of image sensor 104 in accordance with this embodiment. However, in an alternative embodiment, package body 906 extends over image sensor 104 and contacts the periphery of rear surface 104R. In yet another alternative embodiment, package body 906 entirely contacts rear surface 104R and encloses image sensor 104 as indicated by the dashed line 908A. In yet another alternative embodiment, package body 906 is not formed.

FIG. 10 is a cross-sectional view of an image sensor assembly 1000 formed with image sensor package 900 of FIG. 9 in accordance with another embodiment of the present invention. Referring now to FIG. 10, image sensor assembly 1000 includes image sensor package 900 and a system board 202B.

More particularly, image sensor package 900 is mounted to system board 202B. Image sensor package 900 is mounted to system board 202B by system board interconnects 204. Illustratively, system board interconnects 204 are formed by re-flowing interconnection balls 116 (FIG. 9). More particularly, pads 114 of image sensor package 900 are physically and electrically connected to electrically conductive terminals 206 of system board 202B by system board interconnects 204.

System board 202B is formed with an image aperture 1002. As shown in FIG. 10, active area 106 of image sensor 104 of image sensor package 900 is aligned with image aperture 1002 of system board 202B.

Once mounted, front surface 102F of substrate 102B faces towards system board 202B and image aperture 1002. Electromagnetic radiation 210 is directed at and passes through image aperture 1002 of system board 202B. Electromagnetic radiation 210 strikes front surface 102F of substrate 102B. Electromagnetic radiation 210 passes through substrate 102B, through medium 122 and strikes active area 106. Image sensor 104 responds to electromagnetic radiation 210 as is well known to those of skill in the art.

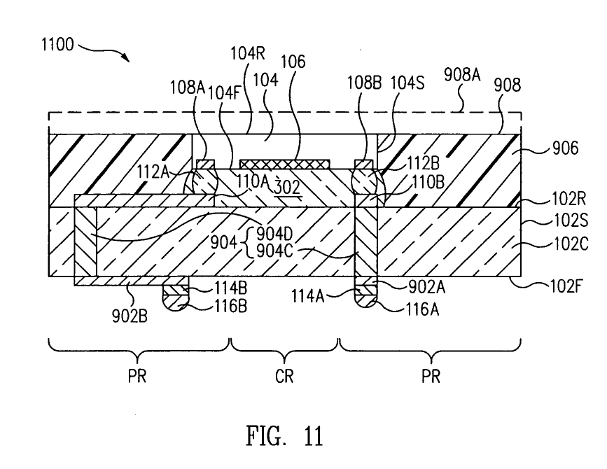

FIG. 11 is a cross-sectional view of an image sensor package 1100 in accordance with an alternative embodiment of the present invention. Package 1100 of FIG. 11 is similar to package 900 of FIG. 9 and only the significant differences are discussed below.

Image sensor package 1100 includes a transparent underfill 302, sometimes called an underfill material, which completely underfills image sensor 104. More particularly, transparent underfill 302 entirely fills the region between front surface 104F of image sensor 104 and rear surface 102R of substrate 102C in a manner similar to that described above with regards image sensor package 300 of FIG. 3. Package body 906 encloses transparent underfill 302, any exposed portions of rear traces 110 and rear surface 102R of substrate 102C, and side 104S of image sensor 104.

As shown in FIG. 11, rear trace 110B and front trace 902A are lands aligned with and electrically connected together by a via 904C of the plurality of vias 904. More particularly, rear trace 110B and front trace 902A are aligned horizontally in the view of FIG. 11 with via 904C, bump 112B, bond pad 108B, pad 114A and interconnection ball 116A.

In contrast, rear trace 110A and front trace 902B are metallizations which extend along rear surface 102R and front surface 102F of substrate 102C, respectively, such that a via 904D of the plurality of vias 904 is not aligned with either bump 112A or pad 114B.

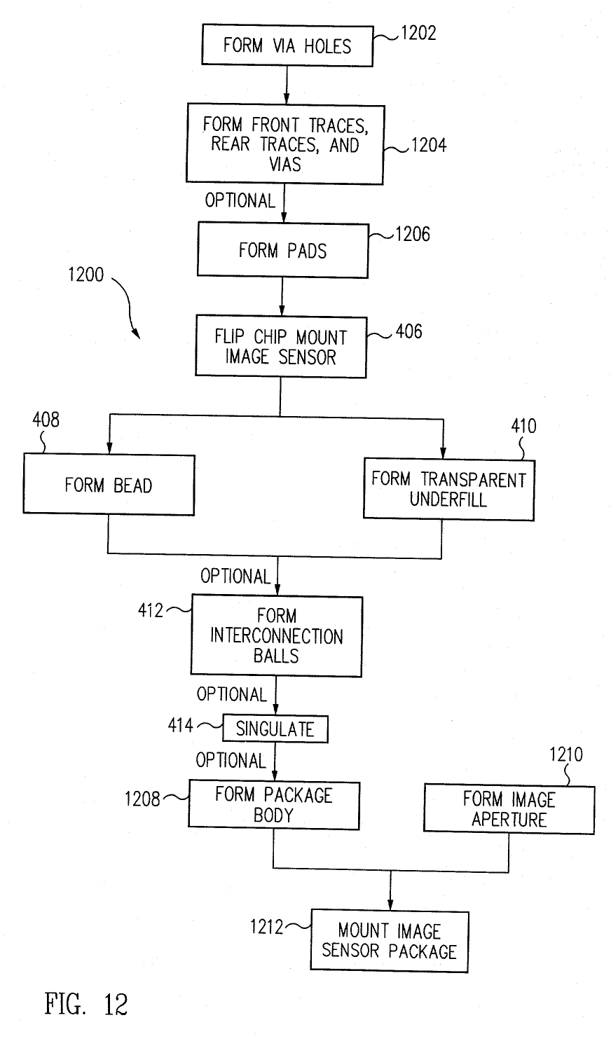

FIG. 12 is a block diagram 1200 illustrating operations in a process for manufacturing image sensor assembly 1000 of FIG. 10 in accordance with one embodiment of the present invention.

Referring now to FIGS. 10 and 12 together, in a Form Via Holes Operation 1202, via holes, sometimes called via apertures, are formed in substrate 102B to extend between front surface 102F and rear surface 102R.

Illustratively, the via holes are formed by mechanical drilling or lasering substrate 102B. Alternatively, the via holes are formed by chemically etching substrate 102B.

In a Form Front Traces, Rear Traces and Vias Operation 1204, front traces 902, rear traces 110 and vias 904 are formed. Illustratively, to form vias 904, an electrically conductive layer, e.g., a copper or copper containing layer, is formed in the via holes, which were formed during Form Via Holes Operation 1202. Further, an electrically conductive layer is formed on rear surface 102R and front surface 102F of substrate 102B and patterned to form front traces 902 and rear traces 110. Alternatively, rear traces 110 and/or front traces 902 are formed separate from substrate 102B and then mounted, e.g., with adhesive, to rear surface 102R and/or front surface 102F of substrate 102, respectively.

Optionally, in a Form Pads Operation 1206, pads 114 are formed on front traces 902. Illustratively, a mask, e.g., photoresist, is formed on substrate 102B to expose portions of front traces 902. Pads 114 are formed, e.g., by plating, on the exposed portions of front traces 902. The mask is then removed.

Flip Chip Mount Image Sensor Operation 406, Form Bead Operation 408 (or alternatively Form Transparent Underfill Operation 410), Form Interconnection Balls Operation 412, and Singulate Operation 414 are performed, if at all, as discussed above in reference to FIG. 4.

Optionally, in a Form Package Body Operation 1208, package body 906 is formed. Illustratively, package body 906 is formed using a transfer molding process as those of skill in the art will understand in light of this disclosure.

In a Form Image Aperture Operation 1210, image aperture 1002 is formed in system board 202B. In a Mount Image Sensor Package Operation 1212, image sensor package 900 is mounted to system board 202B such that active area 106 of image sensor 104 is aligned with image aperture 1002 to complete fabrication of image sensor assembly 1000. More particularly, image sensor package 900 is mounted to system board 202B by forming system board interconnects 204 between pads 114 and terminals 206. In one embodiment, system board interconnects 204 are formed by reflowing interconnection balls 116 (FIG. 9).

This disclosure provides exemplary embodiments of the present invention. The scope of the present invention is not limited by these exemplary embodiments. Numerous variations, whether explicitly provided for by the specification or implied by the specification, such as variations in structure, dimension, type of material and manufacturing process may be implemented by one of skill in the art in view of this disclosure.

1. An image sensor package comprising:
a transparent substrate comprising a base surface and a pocket sidewall;
a trace coupled to said base surface;
an image sensor comprising a first surface comprising an active area and a bond pad;
a bump coupling said bond pad to said trace, wherein said image sensor is located within an image sensor pocket of said transparent substrate defined by said base surface and said pocket sidewall; and
a bead forming a seal between a periphery of said image sensor and said base surface, wherein said image sensor, said bead, and said base surface define a cavity, said active area being located within said cavity.

2. The image sensor package of claim 1 wherein said transparent substrate further comprises a rear surface, said pocket sidewall extending between said base surface and said rear surface, wherein said trace extends from said base surface, along said pocket sidewall, and to said rear surface.

3. The image sensor package of claim 2 wherein said trace comprises:
a first portion extending along said base surface to said pocket sidewall;
a second portion extending along said pocket sidewall from said base surface to said rear surface; and
a third portion extending along said rear surface.

4. The image sensor package of claim 3 wherein said first portion, said second portion, and said third portion are integral.

5. The image sensor package of claim 3 further comprising an interconnection ball coupled to said third portion.

6. The image sensor package of claim 3 further comprising a pad coupled to said third portion.

7. The image sensor package of claim 2 wherein said image sensor is entirely within said image sensor pocket.

8. The image sensor package of claim 7 wherein said image sensor comprises a second surface below said rear surface of said transparent substrate.

9. An image sensor package comprising:
a transparent substrate comprising:
a base surface;
a pocket sidewall; and
a rear surface, said pocket sidewall extending between said base surface and said rear surface;
a trace coupled to said base surface, wherein said trace extends from said base surface, along said pocket sidewall, and to said rear surface;
an image sensor comprising:
a first surface comprising an active area and a bond pad; and
a second surface coplanar with said rear surface of said transparent substrate; and
a bump coupling said bond pad to said trace, wherein said image sensor is located within an image sensor pocket of said transparent substrate defined by said base surface and said pocket sidewall.

10. An image sensor package comprising:
a transparent substrate comprising:
a base surface;
a pocket sidewall; and
a rear surface, said pocket sidewall extending between said base surface and said rear surface;
a trace coupled to said base surface, wherein said trace extends from said base surface, along said pocket sidewall, and to said rear surface;
an image sensor comprising:
a first surface comprising an active area and a bond pad; and
a second surface above said rear surface of said transparent substrate; and
a bump coupling said bond pad to said trace, wherein said image sensor is located within an image sensor pocket of said transparent substrate defined by said base surface and said pocket sidewall.

11-12. (Canceled)

13. The image sensor package of claim 9 further comprising an underfill filling a region between said first surface of said image sensor and said base surface.

14. The image sensor package of claim 13 wherein said underfill contacts and protects said active area.

15-20. (Canceled)

21. An image sensor package comprising:
a transparent substrate comprising:
a base;
a pocket ring coupled to said base;
an image sensor comprising a first surface comprising an active area and a bond pad, wherein said image sensor is located within an image sensor pocket of said transparent substrate; and
a bead forming a seal between a periphery of said image sensor and said base, wherein said image sensor, said bead, and said base define a cavity, said active area being located within said cavity.

22. The image sensor package of claim 21 wherein said base comprises a rectangular piece.

23. The image sensor package of claim 21 wherein said pocket ring comprises a rectangular annulus.

24. The image sensor package of claim 21 wherein said pocket ring is glued to said base.

25. The image sensor package of claim 21 wherein said pocket ring is laminated to said base.
